(19) United States
(12) Patent Application Publication
(10) Pub. No.: US 2006/0001021 A1
(43) Pub. Date: Jan. 5, 2006

(54) Multiple semiconductor inks apparatus and method

(75) Inventors: Hakeem B. Adewole, Schaumburg, IL (US); Paul W. Brazis, South Elgin, IL (US); Daniel R. Gamota, Palatine, IL (US); Jie Zhang, Buffalo Grove, IL (US)

Correspondence Address: FITCH EVEN TABIN AND FLANNERY, 120 SOUTH LA SALLE STREET, SUITE 1600, CHICAGO, IL, 60603-3406, US

(73) Assignee: Motorola, Inc.

(21) Appl. No.: 10/882,015

(22) Filed: Jun. 30, 2004

(51) Int. Cl. H01L 29/08; H01L 21/00

(52) U.S. Cl. 257/40; 438/82

(57) ABSTRACT

A semiconductor device can be comprised of a substrate having a plurality of different printable semiconductor inks formed thereon. In a preferred approach at least some of these printable semiconductor inks comprise organic semiconductor material inks. These semiconductor inks can vary from one another with respect to various properties including but not limited to electrical characteristics and environmental efficacy.

### TECHNICAL FIELD

This invention relates generally to semiconductor devices and more particularly to printable semiconductor inks.

### BACKGROUND

Methods and apparatus that use such techniques as vacuum deposition to form semiconductor-based devices of various kinds are well known. Such techniques serve well for many purposes and can achieve high reliability, small size, and relative economy when applied in high volume settings. Recently, other techniques are being explored to yield semiconductor-based devices. For example, organic semiconductor materials can be provided as a functional ink and used in conjunction with various printing techniques to yield printed semiconductor devices.

Printed semiconductor devices, however, yield considerably different end results and make use of considerably different fabrication techniques than those skilled in the art of semiconductor manufacture are prone to expect. For example, printed semiconductor devices tend to be considerably larger than typical semiconductor devices that are fabricated using more traditional techniques. As other examples, both the materials employed and the deposition techniques utilized are also well outside the norm of prior art expectations.

Due in part to such differences, in many cases existing materials and techniques are not suitable for use and deployment with respect to printed semiconductor devices. Further, in many cases, semiconductor device printing gives rise to challenges and difficulties that are without parallel in prior art practice.

### BRIEF DESCRIPTION OF THE DRAWINGS

The above needs are at least partially met through provision of the multiple semiconductor inks apparatus and method described in the following detailed description, particularly when studied in conjunction with the drawings, wherein:

FIG. 1 comprises a flow diagram as configured in accordance with various embodiments of the invention;

FIG. 2 comprises a side elevational schematic view as configured in accordance with various embodiments of the invention;

FIG. 3 comprises a top plan view as configured in accordance with various embodiments of the invention;

FIG. 4 comprises a schematic as configured in accordance with various embodiments of the invention; and

FIG. 5 comprises a schematic view as configured in accordance with other various embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

Generally speaking, pursuant to these various embodiments, at least one semiconductor device is formed on a substrate using a plurality of different printable semiconductor inks. In a preferred embodiment at least some of these different printable semiconductor inks comprise organic semiconductor materials and the resultant semiconductor device comprises, at least in part, an organic semiconductor device. These printable semiconductor inks can differ from one another in any of a wide variety of ways including, but not limited to, with respect to various electrical performance attributes and/or with respect to environmental robustness.

These teachings permit a wide breadth of design variability. Accordingly, a relatively wide variation of circuit design and circuit performance can be accommodated. This, in turn, can facilitate or even favor the use of printed organic semiconductor devices in applications where such an approach might not otherwise seem useful or possible.

These and other benefits will become more evident to those skilled in the art upon making a thorough review and study of the following detailed description.

Referring now to the drawings, and in particular to FIG. 1, an overall process 10 to facilitate provision of a semiconductor device comprises providing 11 a substrate and then forming 12 at least one semiconductor device on the substrate using a plurality of different printable semiconductor inks. The substrate can comprise any material or form factor as may compatibly comport with these teachings while also meeting the needs and or limitations of a given application. Printing techniques are employed in a preferred embodiment and hence the substrate can comprise, if desired, a flexible substrate such as, but not limited to, a polyester substrate or a paper substrate.

In a preferred embodiment the printable semiconductor inks are comprised of different semiconductor materials including preferably organic semiconductor materials. As one illustrative example, the semiconductor device can itself be comprised of a plurality of semiconductor devices. In such an example, a first one of the plurality of semiconductor devices can be comprised of a first semiconductor material while a second one of the plurality of semiconductor devices comprises a second semiconductor material that differs from the first semiconductor material. Pursuant to another approach, a single semiconductor may itself comprise two or more different semiconductor materials.

Those skilled in the printing arts are familiar with both graphic inks and so-called functional inks (wherein “ink” is generally understood to comprise a suspension, solution, or dispersent that is presented as a liquid or paste, or a powder (such as a toner powder). These functional inks can be comprised of metallic, organic, or inorganic materials and can have variety of shapes (spherical, flakes, fibers, tubes, and so forth), with particle sizes of a few microns to a few nanometers, or that are completely dissolved into solutions. Such Functional inks find application, for example, in the manufacture of some membrane switches. Though graphic inks can be employed as appropriate in combination with this process 10, the printable semiconductor inks are more likely, in a preferred embodiment, to comprise a functional ink.

These semiconductor materials can differ from one another in any of a wide variety of ways as corresponds to the needs of a given application and setting. To illustrate, these printable semiconductor inks can differ from one another at least with respect to an electrical performance attribute such as, but not limited to, solute/dispersant concentration, temperature dependence, conductivity, majority carrier type, and/or field effect mobility, to note a few. As another illustration, these printable semiconductor inks can differ from one another at least with respect to environmental robustness. For example, some organic semiconductor materials are relatively sensitive to the presence or impingement of water, oxygen, ultraviolet radiation, and/or any number of other ambient forces or constants. It may be useful and desirable in some instances to use materials that vary with robustness to such factors for various devices (or for different parts of a given device) to facilitate a particular design goal, feature, or capability.

In a preferred approach, such printable semiconductor inks are formed 12 on the substrate by use of a corresponding printing technique. Those familiar with traditional semiconductor fabrication techniques such as vacuum deposition will know that the word “printing” is sometimes used loosely in those arts to refer to such techniques. As used herein, however, the word “printing” is used in a more mainstream and traditional sense and does not include such techniques as vacuum deposition that involve, for example, a state change of the transferred medium in order to effect the desired material placement. Accordingly, “printing” will be understood to include such techniques as screen printing, offset printing, gravure printing, xerographic printing, flexography printing, inkjetting, microdispensing, stamping, and the like. It will be understood that these teachings are compatible with the use of a plurality of such printing techniques during fabrication of a given semiconductor device. For example, it may be desirable to print a first semiconductor ink using a first printing process and a second, different semiconductor ink using a second, different print process.

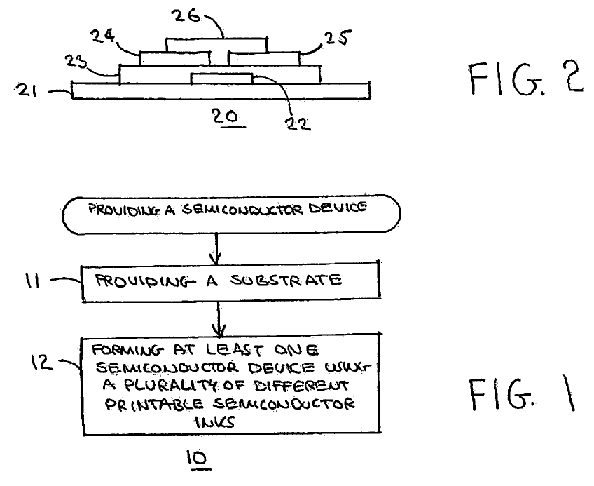

With reference to FIG. 2, a schematic representation of a given semiconductor device (or a portion of a semiconductor device) 20 as formed in accordance of these teachings will now be briefly described. A substrate 21, such as a flexible substrate, has a first conductive material (such as a polymer thick film (PTF) conductor or other conductive polymer, an organo-metallic material, a nanoparticle ink, and/or a metal foil to name a few) deposited thereon to thereby form a gate 22. A dielectric layer 23 comprised, for example, of PTF dielectric material, a polymer, and/or certain oxides) is then deposited over and, in a preferred embodiment, about the gate 22.

Two additional areas of conductive material 24 and 25 are then deposited on the dielectric layer 23 to thereby form a source (24) and a drain (25). In a preferred embodiment and in accord with well-understood practice, a small gap between the source and drain is positioned opposite the gate 22. A layer of ink comprising, in this embodiment, organic semiconductor material 26 (comprised of, for example, polymers (including but not limited to organic polymers such as polythiophene, polyacetylene, poly(9,9-dictylfluorene-co-bithiophene)), small molecule-based materials such as pentacene, sexithiophene, and phthalocyanine, or any of a variety of oligomers) or, in an appropriate embodiment, an ink comprising a non-organic semiconductor material is then deposited to at least bridge the gap between the source and drain. Pursuant to these teachings, this application of semiconductor material 26 can itself comprise an application of two or more differing kinds of semiconductor material as may facilitate attainment of a given corresponding performance capability or attribute. Or, and as will now be described in more detail, multiple such field effect transistors can be employed to fabricate a larger semiconductor device.

Referring now to FIG. 3, an inverter circuit can be comprised of two such field effect transistors comprising, in this embodiment, a drive device 20A and a load device 20B as are formed on a shared substrate 21. The drive device 20A and the load device 20B each comprise, in this embodiment, a printed gate 22A/22B that couples to a corresponding conductive pad, a printed dielectric layer 23A/23B, a printed source and drain 24A and 25A/24B and 25B, and a printed semiconductor layer 26A/26B.

In this embodiment, the printed semiconductor inks used to print these semiconductor layers 26A and 26B differ from one another with respect to their electrical properties. In particular, the semiconductor material for the drive device 20A has a relatively low on-current as compared to the semiconductor material used for the load device 20B. For example, the semiconductor material for the drive device 20A can have an on-current that is two or three orders of magnitude lower than that of the semiconductor material for the load device 20B. The load device 20B, in turn, will preferably have a semiconductor material characterized by a relatively high on-current. For example, the on-current as corresponds to this material will be several orders of magnitude higher than any leakage current from the gates including particularly the drive transistor gate and the drive device transistor 20A.

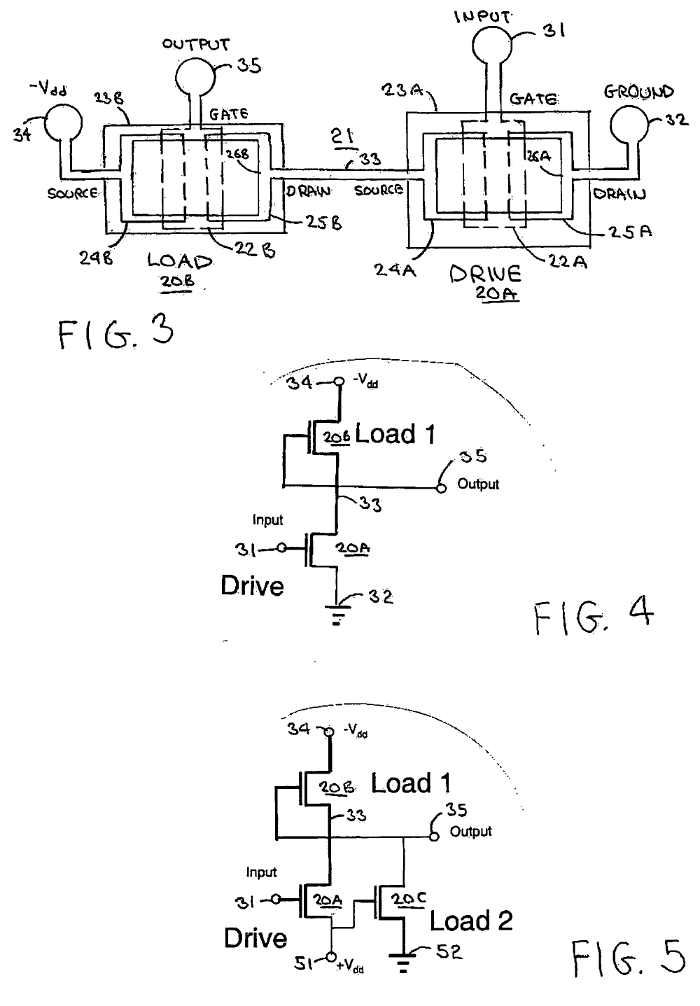

So configured, the drive device 20A has an input 31 operably coupled to the gate 22A, a drain 25A operably coupled to a ground connection 32, and a source 24A that couples via a conductor 33 to the drain 25B of the load device 20B. The source 24B of the load device 20B operably couples to an appropriate potential 34 (−V_{dd} in this illustrative example) and an output pad 35 that operably couples to the gate 22B thereof. FIG. 4 comprises a schematic electrical component diagram as corresponds to the two-device semiconductor device described above with respect to FIG. 3.

Various benefits can be attained by use of different semiconductor inks when printing semiconductor devices. In the example presented above, by using a more conductive semiconductor for the drive device and a more resistive material for the load device, an improved voltage swing in the inverter output can be expected as compared to a circuit fabricated in accord with prior art practice, while keeping both devices physically the same size. This may be useful for large-area printing technologies, where printing resolution may be limited. Different semiconductors would therefore allow both optimized performance and minimum physical transistor size.

As another illustrative example, and referring now to FIG. 5, a three-transistor semiconductor device can comprise a drive device 20A and a first load device 20B as described above, along with a second load device 20C. This second load device 20C can comprise a transistor essentially configured and arranged as described above with the exception that the semiconductor material for this second load device 20C can differ from the semiconductor material used for the drive device 20A and the load device 20B in that the second load device 20C semiconductor material can be characterized by a reduced on-current, plus an intentionally reduced on-off ratio that is several orders of magnitude lower than both the drive device 20A and the first load device 20B. In addition, in this embodiment, the drain of the drive device can couple to a biasing potential 51 (such as +V_{dd}) while the drain of the second load device 20C can operably couple to ground 52. Such a material and such a configuration will permit, for example, yet further improved voltage swing in the inverter output and will also produce sufficient voltage to drive a following stage ring oscillator.

These teachings permit the use of multiple semiconducting materials to facilitate enhanced design flexibility when seeking to optimize the performance of a printed circuit including particularly printed organic semiconductor active devices. This can lead to improvements with respect to overall size or device footprint, electrical power consumption, switching speed, and other measures of performance.

Those skilled in the art will recognize that a wide variety of modifications, alterations, and combinations can be made with respect to the above described embodiments without departing from the spirit and scope of the invention, and that such modifications, alterations, and combinations are to be viewed as being within the ambit of the inventive concept. For example, as noted above, it may useful in some designs to use semiconductor materials that differ with respect to their majority carrier type. To illustrate, it would be possible to employ both a first semiconductor material ink characterized by N-type properties and a second semiconductor material ink characterized by P-type properties. Also, though illustrated above through use of organic semiconductor materials, these teachings may also be applicable for use with other semiconductor materials (and/or with a combination of organic and non-organic semiconductor materials) as are presently known or hereafter-developed. Those skilled in the art will also understand and appreciate that such techniques can be further employed to develop passive devices for circuit biasing applications by using different semiconductor materials to control or otherwise influence the behavior of the resultant device.

We claim:

1. A method to facilitate provision of at least one semiconductor device comprising:
providing a substrate;
forming on the substrate at least one semiconductor device using a plurality of different printable semiconductor inks.

2. The method of claim 1 wherein providing a substrate further comprises providing a flexible substrate.

3. The method of claim 2 wherein providing a flexible substrate further comprises providing a polyester substrate.

4. The method of claim 2 wherein providing a flexible substrate further comprises providing a paper substrate.

5. The method of claim 1 wherein forming on the substrate at least one semiconductor device using a plurality of different printable semiconductor inks further comprises forming on the substrate a plurality of organic semiconductor devices using a plurality of different semiconductor materials.

6. The method of claim 5 wherein forming on the substrate a plurality of organic semiconductor devices using a plurality of different semiconductor materials further comprises forming on the substrate a plurality of organic semiconductor devices using a first semiconductor material for a first one of the plurality of organic semiconductor devices and a second semiconductor material, which second semiconductor material is different from the first semiconductor material, for a second one of the plurality of organic semiconductor devices.

7. The method of claim 1 wherein forming on the substrate at least one semiconductor device using a plurality of different printable semiconductor inks further comprises using a plurality of different semiconductor material inks.

8. The method of claim 7 wherein using a plurality of different semiconductor material inks further comprises using a plurality of different semiconductor material functional inks.

9. The method of claim 1 wherein forming on the substrate at least one semiconductor device using a plurality of different printable semiconductor inks further comprises using a plurality of different semiconductor materials wherein the semiconductor materials differ from one another at least with respect to an electrical performance attribute.

10. The method of claim 1 wherein forming on the substrate at least one semiconductor device using a plurality of different printable semiconductor inks further comprises using a plurality of different semiconductor materials wherein the semiconductor materials differ from one another at least with respect to environmental robustness.

11. An apparatus comprising:
a substrate;
at least a first semiconductor device formed on the substrate comprised of at least two differing printable semiconductor inks.

12. The apparatus of claim 11 wherein the at least two differing printable semiconductor inks comprise at least two differing printable organic semiconductor material inks.

13. The apparatus of claim 11 wherein the at least two differing printable semiconductor inks comprise inks that have been printed with respect to the substrate.

14. The apparatus of claim 11 wherein the at least a first semiconductor device further comprises at least two organic semiconductor devices.

15. The apparatus of claim 14 wherein each of the at least two organic semiconductor devices are comprised of at least two different printable semiconductor inks.

16. The apparatus of claim 15 wherein a first one of the at least two organic semiconductor devices is comprised of a first printable semiconductor ink and a second one of the at least two organic semiconductor devices is comprised of a second printable semiconductor ink, which second printable semiconductor ink is different from the first printable semiconductor ink.

17. The apparatus of claim 11 wherein the at least two differing printable semiconductor inks differ from one another with respect to an electrical property.

18. The apparatus of claim 17 wherein the electrical property comprises conductivity.

19. The apparatus of claim 17 wherein the electrical property comprises majority carrier type.

20. The apparatus of claim 17 wherein the electrical property comprises field effect mobility.

21. A method comprising:
providing a substrate;
printing at least a first semiconductor device on the substrate using at least two different printable semiconductor material inks.

22. The method of claim 21 wherein printing at least a first semiconductor device on the substrate using at least two different printable semiconductor material inks further comprises printing at least a first semiconductor device on the substrate using at least two different printable semiconductor material inks, wherein at least one of the two different printable semiconductor material inks comprises a printable organic semiconductor material ink.

23. The method of claim 22 wherein printing at least a first semiconductor device on the substrate using at least two different printable semiconductor material inks further comprises printing at least a first semiconductor device on the substrate using at least two different printable semiconductor material inks, wherein both of the at least two different printable semiconductor material inks comprise a printable organic semiconductor material ink.

24. The method of claim 21 wherein printing at least a first semiconductor device on the substrate further comprises printing at least a first and a second semiconductor device on the substrate.

25. The method of claim 24 wherein printing at least a first and a second semiconductor device on the substrate further comprises printing the first semiconductor device on the substrate using a first printable semiconductor material and printing the second semiconductor device on the substrate using a second printable semiconductor material, which second printable semiconductor material is different from the first printable semiconductor material.

26. The method of claim 21 wherein printing comprises at least one of:
screen printing;
offset printing;
gravure printing;
xerographic printing;
flexography printing;
inkjetting;
microdispensing;
stamping.
